(19) United States
(12) Patent Application Publication
(10) Pub. No.: US 2025/0081648 A1
(43) Pub. Date: Mar. 6, 2025

(54) MULTISPECTRAL FILTER FOR ELECTROMAGNETIC RADIATION AND METHOD FOR MANUFACTURING SAID FILTER

(71) Applicant: COMMISSARIAT À L’ENERGIE ATOMIQUE ET AUX ENERGIES ALTERNATIVES, PARIS (FR)

(72) Inventors: Ujwol PALANCHOKE, GRENOBLE CEDEX 9 (FR); Sébastien BERARD-BERGERY, GRENOBLE CEDEX 9 (FR); Stefan LANDIS, GRENOBLE CEDEX 9 (FR)

(21) Appl. No.: 18/818,077

(22) Filed: Aug. 28, 2024

(30) Foreign Application Priority Data
Aug. 29, 2023 (FR) 2309032

(51) Int. Cl. H01L 27/146; H01L 33/46

(52) U.S. Cl. CPC H10F 39/8053; H10H 20/862

(57) ABSTRACT

A multispectral filter for electromagnetic radiation, the filter including at least two-colour filters, each colour filter including: a metal grating including metal patterns repeated according to a given period, each metal pattern being spaced apart from an adjacent metal pattern by a given non-zero spacing; a continuous reflective layer; a pattern of dielectric material of Fabry-Perot cavity between the metal grating and the continuous reflective layer; the thickness of the patterns of dielectric material of the two-colour filters being different.

### CROSS-REFERENCE TO RELATED APPLICATIONS

This application claims priority to French Patent Application No. 2309032, filed Aug. 29, 2023, the entire content of which is incorporated herein by reference in its entirety.

### FIELD

The technical field of the invention is that of spectral filtering, especially for imaging applications and making coloured filters for CMOS-type image sensors, liquid crystal display devices or light-emitting diodes. The invention can also be implemented in light-emitting devices.

This invention relates to a multispectral filter for electromagnetic radiation.

### BACKGROUND

A spectral filter or colour filter makes it possible to filter light by wavelength, so as to provide information about the intensity of light in some wavelengths. Several colour filters can be associated so as to form, for example, red-green-blue (RGB) filters that inform about the intensity of these three colours.

Metal/dielectric type colour filters made from a Fabry-Perot cavity are especially known. These filters comprise one or more dielectric (or possibly semiconducting) cavities formed between two thin metal films having a metal mirror function so as to form a Fabry-Perot cavity. Generally, the metal/dielectric stacks are different depending on the position on the optoelectronic component (an image sensor, for example). The transmission wavelength of the filter is tuned by adjusting the thickness of the cavity. Thus, in operation, part of the incident light corresponding to the wavelength of the filter is transmitted through it in the form of a coloured beam, while the rest of the incident light is reflected. Generally speaking, the thickness of the dielectric layer sets the central wavelength transmitted, while the thickness of the metal layers makes it possible to tune the transmission spectral width. Furthermore, the use of several Fabry-Perot cavities makes it possible to modify the spectral transmission profile of the filter. A filter of this type is made using conventional semiconductor manufacturing techniques. Thus, to obtain a red-green-blue filter, it is advisable to form at least one dielectric cavity the thickness of which has to have three different values. For some applications, it may be interesting to tune not only the central transmission wavelength (via the thickness of the dielectric layer) but also the transmission passband.

The passband of transmitted spectra can especially be adjusted by varying thickness of the metal [cf. I. L. Gomes de Souza, V. F. Rodriguez-Esquerre and D. F. Rêgo, “Filtres grand angle à base de nanorésonateurs pour le spectre visible”, Appl. Opt. 57, 6755-6759 (2018)]. FIG. 1 shows the spectral response of a Fabry-Perot cavity filter 1 including a 140 nm thick dielectric layer 2 between two reflective metal layers 3 and 4 of the same thickness when the two thicknesses of the metal reflective layers 3 and 4 vary between 10 and 60 nm. The figure shows that by increasing the thickness of the metal of the two layers 3 and 4, the transmission passband decreases (from about 100 nm to about 10 nm). Simultaneously, however, a decrease in maximum transmission from 0.9 to about 0.2 is noticed. There is therefore a negative counterpart on the value of the maximum transmission when it is attempted to reduce the passband of the filter.

Tuning the passband can also be made by varying a single metal thickness, for example the thickness of the reflective layer 4, as illustrated in FIG. 2 (the thickness of the reflective layer 3 remaining constant and equal to 30 nm). However, from the simulation results, it can again be noticed that by increasing the thickness of a single metal layer, the maximum transmission decreases. It therefore appears to be difficult to obtain a narrow transmission passband while maintaining a higher transmission coefficient with Fabry-Perot cavity filters.

One known solution for achieving a good compromise between a narrow passband and maximum transmission that is not too reduced consists in using guided mode resonance (GMR) filters. These filters can be implemented in the visible or infrared range. An example of such a filter can be found in the publication “Structures métal-diélectriques à résonance de mode guidé et applications au filtrage et à l′imagerie infrarouge” (Optics/Photonic. Ecole Polytechnique X, 2013-Sakat et al.). FIG. 3 illustrates the structure of a GMR filter 10 in the infrared. The filter 10 includes a metal grating 11 including metal patterns spaced apart by a spacing w (thus forming slots between each pattern) placed on a dielectric layer 12 which acts as a waveguide. The metal patterns are repeated according to a period d. The coupling between waveguide mode and resonances of the metal patterns gives a resonance wavelength. The wavelength essentially depends on the thickness of the dielectric layer 12. By adjusting the different parameters, especially the period p, the spacing w and the thickness of the metal patterns tm, it is possible to reduce transmission passband while keeping an acceptable maximum transmission.

More recently, filter structures including a dielectric layer sandwiched between two metal gratings have been described, operating in both the visible and infrared ranges. An example of such a filter 20 is represented in FIG. 4. The filter 20 includes a first metal grating 21 including metal patterns disposed periodically according to a period d and spaced apart by a spacing a, placed on a dielectric layer 22 which acts as a waveguide, itself above a second metal grating 23 similar to the first grating 21. Once again, the different parameters which are the thickness td of the dielectric layer, the period d, the spacing a and the thickness of the metal patterns tm make it possible to tune the transmission wavelength, passband and maximum transmission.

Although the structure shown in FIG. 3 offers satisfactory performance in terms of compromise between maximum transmission and passband width, it remains not very well adapted to an implementation with multispectral filters using pixelated sensors. Indeed, such an application would require several different colour filters (typically red, blue and green) to be made in the same structure, each with two different metal gratings. Such a structure 30 is illustrated in FIG. 5. It comprises 3 filters (Pixel i, i varying from 1 to 3) each including respectively:
a first metal grating 31Pi including metal patterns disposed periodically according to a period Pi and spaced apart by a spacing Wi,
a dielectric layer 32Pi which acts as a waveguide,
a second metal grating 33Pi.

It will be noted that each dielectric layer 32Pi has a different thickness to let the corresponding wavelength pass therethrough.

Thus, two (lower and upper) metal gratings have to be manufactured using standard lithography techniques. While the lower grating 31Pi can be obtained in a standard way, the upper grating 33Pi is much more complex to make on dielectric layers of different thicknesses, especially because of the necessary alignment of the upper and lower two metal gratings and the need to control the periods and the different spacings for the gratings of each pixel. Such manufacture requires numerous technologically complex steps.

Furthermore, for the guided mode resonance filter to operate efficiently, a higher repetition of the grating period is necessary. In addition, to obtain transmission of different wavelengths, a different grating period has to be used for each pixel. The difficulty in mastering technological making of gratings can therefore lead to performance problems for pixelated image sensors. Finally, with a predefined pixel size for each pixel, the number of metal patterns is different for the different pixels, again leading to manufacturing difficulties.

### SUMMARY

Aspects of the invention offer a solution to the problems previously discussed, by providing a multispectral filter for electromagnetic radiation with a good compromise between maximum transmission for each wavelength and passband width, while dispensing with the manufacturing problems mentioned above.

To this end, one aspect of the invention is a multispectral filter for electromagnetic radiation, said filter including at least two colour filters, each colour filter including:
a metal grating including metal patterns repeated according to a given period, each metal pattern being spaced apart from an adjacent metal pattern by a given non-zero spacing;
a continuous reflective layer;
a pattern of dielectric material of Fabry-Perot cavity between the metal grating and the continuous reflective layer;
   the thickness of the patterns of dielectric material of the two colour filters being different.

By virtue of the invention, the Fabry-Perot cavity filter is made with a conventional continuous metal reflector, while the second reflector is a discontinuous metal grating of the “metal grating layer” type. Such an architecture offers both the tuning flexibility of double grating filters and manufacturing simplicity in that only a discontinuous layer has to be made. Furthermore, it is perfectly possible to make a filter in accordance with the invention enabling different colours (red, blue, green, for example) to be filtered with a repetition period for the patterns of the metal grating that remains constant, whatever the colour, and by adjusting, for example, the spacing between the patterns from one colour to another. As will be seen later, the filter according to an aspect of the invention makes it possible to obtain more satisfactory performance in terms of compromise between maximum transmission and narrowness of the passband (especially compared with conventional filters wherein the metal thickness is increased). It will be noted that the filter according to the invention acts as a Fabry-Perot cavity resonator formed by the “continuous metal layer-dielectric layer—metal grating” tri-layer and that the filtered wavelength is essentially determined by the thickness of the dielectric layer. The presence of at least two different thicknesses therefore ensures operation over at least two wavelengths and thus the making of a pixelated filter, each pixel corresponding to a wavelength.

Further to the characteristics just discussed in the previous paragraph, the filter according to one or more aspects of the invention may have one or more additional characteristics from among the following, considered individually or according to any technically possible combinations:
the repetition period of the metal patterns is identical for the two colour filters; the filter according to an embodiment of the invention can keep this identical period for any number of colour filters greater than or equal to 2;
the thickness of the metal grating of the two colour filters is identical; the filter according to an embodiment of the invention can keep this identical thickness for any number of colour filters greater than or equal to 2;
the thickness of the reflective layer of the two colour filters is identical; the filter according to an embodiment of the invention can keep this identical thickness for any number of colour filters greater than or equal to 2;
each of the two filters faces a photoelectric transducer. By “photoelectric transducers”, it is meant devices that can operate either as collectors of light from the filters or as emitters of light towards the filters. In the case of collectors, the transducers can be CMOS-type photodiodes, for example. In the case of emitters, the transducers can be LED diodes, QLED-type diodes or LASER diodes, in which case the emitters have a wider emission spectrum than that of the corresponding Fabry-Perot cavities;
the space between each metal pattern is filled with the dielectric material forming the patterns of dielectric material of Fabry-Perot cavity of the colour filters;
the repetition period of the metal patterns in each metal grating is chosen to be strictly less than the wavelength of the corresponding colour filter;
it will be noted that the metal gratings are located, in an embodiment, on the lower part of the filter while the continuous reflective layers are located on the upper part of the filter for reasons of ease of manufacture; however, it will be seen that it is also possible to manufacture a multispectral filter according to an embodiment of the invention with metal gratings located on the upper part of the filter and continuous reflective layers located on the lower part of the filter.

An aspect of the invention is also a method for manufacturing a multispectral filter for electromagnetic radiation according to a first embodiment of the invention including the following steps of:
Depositing a first resin layer onto a substrate;
Structuring the first resin layer so as to obtain at least two series of trenches in the first resin layer, each trench in a series being spaced apart from an adjacent trench in the series by a given non-zero spacing, the trenches being repeated according to a given period;
Depositing a metal layer into the trenches and onto the remaining resin;
Removing the remaining resin and the metal being on the remaining resin so as to keep two metal gratings each including metal patterns repeated according to the given period of one of the series of trenches, each metal pattern being spaced apart from an adjacent metal pattern by the given non-zero spacing of one of the series of trenches;
Depositing a planar layer of dielectric material intended to form at least two patterns of dielectric material of Fabry-Perot cavity, said layer having the maximum thickness of the dielectric pattern of Fabry-Perot cavity;
Depositing a resin layer onto the layer of dielectric material and removing said resin layer with a stop on the dielectric layer at the zone above one of the two metal gratings;
Etching the dielectric layer at the resin removal zone so as to obtain a first dielectric pattern of Fabry-Perot cavity;
Removing the remaining resin so as to reveal a second dielectric pattern of Fabry-Perot cavity having the maximum dielectric pattern thickness, the thickness of the first dielectric pattern being less than the thickness of the first dielectric pattern;
Depositing a continuous metal layer onto the first and second dielectric patterns.

According to this first manufacturing mode, the metal gratings are located on the lower part of the filter, while the continuous reflective layers are located on the upper part of the filter.

Another aspect of the invention is also a method for manufacturing a multispectral filter for electromagnetic radiation according to a second embodiment of the invention including the following steps of:
Depositing a layer of structuring material onto a substrate;
Structuring the layer of structuring material so as to obtain at least two structuring material patterns of different heights, at least one of the patterns having a maximum reference height relative to the substrate, the height being measured perpendicularly to the plane of the substrate;
Depositing a continuous metal layer onto the at least two structuring material patterns;
Depositing a layer made of the dielectric material intended to form at least two dielectric patterns of Fabry-Perot cavities, said layer of dielectric material covering all the structuring material patterns and having an upper surface, each point of which is located at a height greater than the maximum reference height;
Planarising by removal of the dielectric material with a selective stop at the top of the uppermost structuring material pattern covered by the continuous metal layer;
Depositing a layer made of the same dielectric material so as to finalise the formation of the at least two dielectric patterns of Fabry-Perot cavity;
Depositing a second metal layer on the at least two dielectric patterns of Fabry-Perot cavity;
Structuring the second metal layer so as to form at least two metal gratings each including metal patterns repeated according to a given period, each metal pattern being spaced apart from an adjacent metal pattern by a given non-zero spacing.

According to this second manufacturing mode, the multispectral filter according to the invention includes metal gratings located on the upper part of the filter and continuous reflective layers located on the lower part of the filter.

Beneficially, the structuring material is a resin, said structuring step being carried out by a so-called grayscale lithography step on the layer of structuring material.

The invention and its different applications will be better understood upon reading the following description and upon examining the accompanying figures.

### BRIEF DESCRIPTION OF THE FIGURES

The figures are set forth by way of indicating and in no way limiting purposes of the invention.

FIG. 1 illustrates effect of the thickness of the two reflective layers of a state-of-the-art Fabry-Perot cavity filter on the transmission and passband of the filter;

FIG. 2 illustrates effect of the thickness of one of the two reflective layers of a state-of-the-art Fabry-Perot cavity filter on the transmission and passband of the filter;

FIG. 3 illustrates a single metal grating guided mode resonance GMR filter according to the state of the art;

FIG. 4 illustrates a double metal grating guided mode resonance GMR filter according to the state of the art;

FIG. 5 illustrates a multispectral filter including a plurality of filters according to [FIG. 4];

FIG. 6 illustrates a multispectral filter according to a first embodiment of the invention;

FIG. 7 shows a comparison of the transmission spectra for three different colour filter structures, including one colour filter used in a filter according to an embodiment of the invention;

FIG. 8 and FIG. 9 show the spectral responses of a multispectral filter according to the state of the art and a multispectral filter according to an embodiment of the invention;

FIG. 10 shows a transmission mapping as a function of the spacing between the patterns of a metal grating of a colour filter of a multispectral filter according to an embodiment of the invention;

FIG. 11 shows another example of the spectral response of a multispectral filter according to an embodiment of the invention with a different period from that in FIGS. 8 and 9;

FIG. 12 illustrates the different steps of a method for manufacturing a multispectral filter according to the first embodiment of the invention;

FIG. 13 illustrates a multispectral filter according to a second embodiment of the invention.

FIG. 14 shows the superposition of the spectral response of two colour filters used respectively in the filter in FIG. 6 and in the filter in FIG. 13;

FIG. 15 illustrates the different steps of a method for manufacturing a multispectral filter according to the second embodiment of the invention.

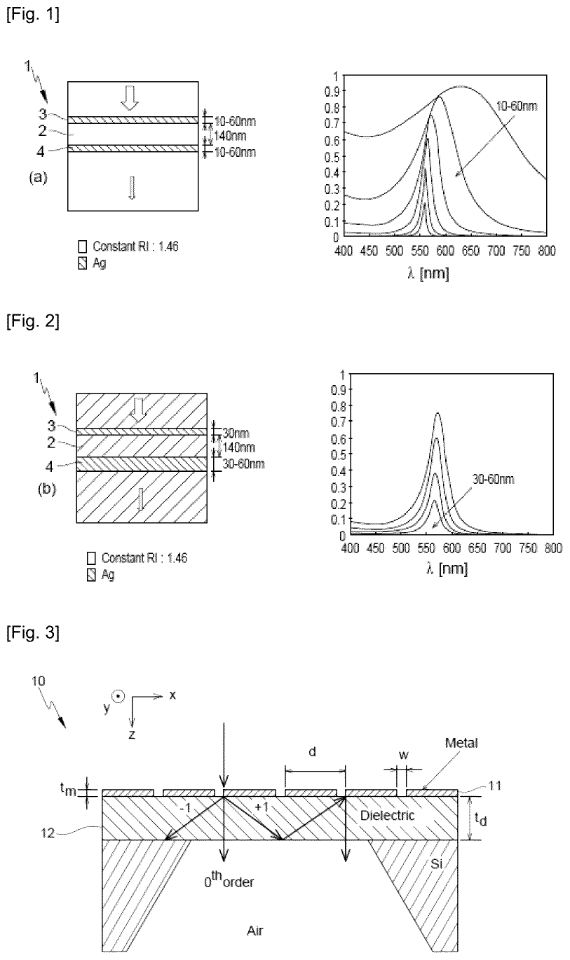

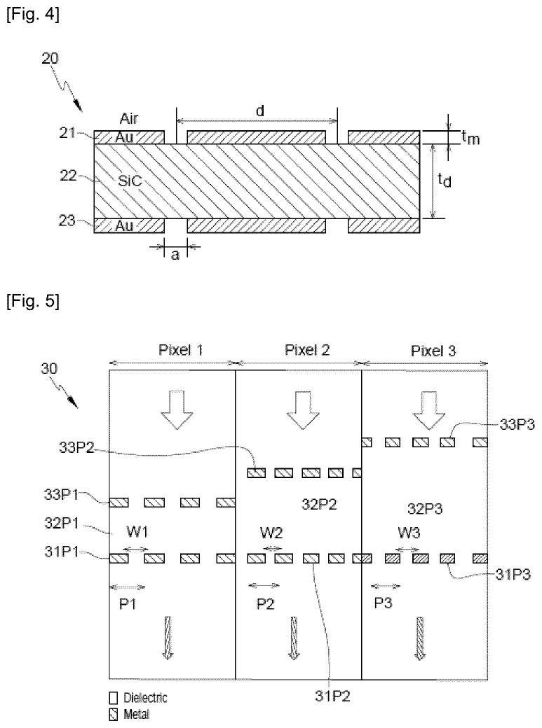

### DETAILED DESCRIPTION

The figures are set forth by way of indicating and in no way limiting purposes of the invention.

It should be first reminded that, in general and well known to those skilled in the art, a metal/dielectric type colour filter made from a Fabry-Perot cavity is obtained by dimensioning the thickness of the dielectric layer formed between the two metal layers. If filtering of several colours is required on a same component, it is then necessary to be able to obtain a dielectric of variable thickness on this same component.

This dimensioning is carried out, for example, using an electromagnetic calculation program such as the Abeles matrix transfer formalism or a diffraction calculation for pixels the size of which is close to the wavelength, such as the formalism of the Modal Method by Fourier Expansion or Rigorous Coupled Wave Analysis (RCWA).

These calculation programs make it possible to determine optimum parameters for the metal-dielectric stacks for each pixel. The calculation thus takes account of the thicknesses of the metal and dielectric layers as well as their indices, the spectrum and the angular distribution of the incident light. For example, in the case of Fabry-Perot filters, the central wavelength of the filter is determined approximately by the following formula:

$${λ}_{0} = \frac{2 π {h}_{cavity} \sqrt{{n}_{cavity}^{2} - {sin}^{2} {θ}_{in}}}{π + φ}$$

where
h_{cavity} is the thickness of the cavity, that is, approximately the thickness of the dielectric layer
n_{cavity} is the effective index of the cavity,
φ is the phase shift on reflection on the metal mirror (determined by the nature of the materials involved and the wavelength considered),
θᵢₙ is the angle of incidence of the incident light on the filter (counted from the perpendicular to the surface of the filter).

Once the angle of attack, index and phase shift are known, all that remains is then to determine an approximate thickness for the cavity to be centred on a particular wavelength. Once the filter function has been calculated for each filter and each wavelength, the thicknesses h of the dielectrics are then adjusted as a function of the performance required (search for a good signal-to-noise ratio, maximum transmission, etc.).

Another, more empirical method consists in calculating the response of the stack for several thicknesses h and choosing h such that the filter resonance peak (2 res) is positioned in accordance with the specifications.

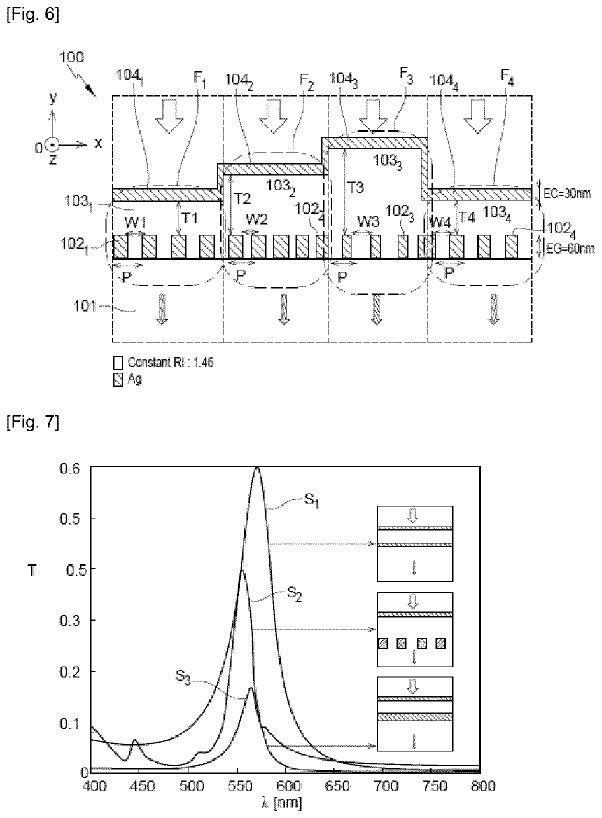

FIG. 6 illustrates a multispectral filter 100 according to an embodiment of the invention.

The multispectral filter 100 includes a plurality of colour filters Fi (i being an integer greater than or equal to 2) made on a substrate 101 which may be, for example, a Si substrate, a Silicon On Insulator (SOI) substrate or a glass or sapphire substrate. Here, 4 colour filters F1 to F4 (including two identical filters F1 and F4) are represented for illustration purposes only.

The aim of each colour filter Fi is to let a transmission spectrum pass through with a given central length, a given maximum transmission and a given passband and includes:
A discontinuous reflective metal layer 102i formed by a substantially planar metal grating including a plurality of metal patterns 103i, each metal pattern 103i being repeated with a period P measured along the axis Ox, being spaced apart from the adjacent pattern(s) by a non-zero spacing Wi measured along the axis Ox and having a thickness EG measured along the axis Oy (Oxy being the plane of the figure and the axis Oy being along the direction perpendicular to the plane of the substrate 101);
A dielectric layer 103i of thickness Ti forming a dielectric pattern of Fabry-Perot cavity, said layer being in contact on its lower surface with the discontinuous metal layer 102i;
A continuous reflective metal layer 104i of thickness EC measured along the axis Oy in contact with the upper surface of the dielectric layer 103i.

The metal patterns of the gratings 102i are represented here in the form of parallelepipedal blades extending along the axis Oz perpendicular to Oxy, it being understood that these patterns may have other shapes such as cylindrical pillars (square, circular, elliptical, etc.) spaced apart from one another by a spacing Wi and repeated according to a period P.

In an embodiment, the period P is constant for all the metal gratings 102i. The same applies to the thickness EG, which is also, in an embodiment, constant for all the metal gratings 102i, and to the thickness EC, which is also, in an embodiment, constant for all the continuous reflective layers 104i. The repetition period P is beneficially chosen to be strictly less than the wavelengths of the colour filters forming the filter according to an embodiment of the invention.

The material used for the reflective metal layers 102i and 104i is, in an embodiment, identical and may be, for example, Ag or Au for applications in the visible range.

The material used for the dielectric patterns 103i can be, for example, SiO₂, SiN or even a resin intended for use in lithography.

Beneficially, each space between the metal patterns of the gratings 102i is filled with the dielectric material used for the dielectric patterns 103i.

The set of metal layers 104i can be seen as a continuous metal layer of constant thickness EC with staircase steps covering the upper surfaces of the dielectric patterns 103i as well as, optionally, the flanks thereof.

The set of metal gratings 102i can be seen as a planar metal grating with a constant repetition period P of metal patterns the spacing Wi of which between adjacent patterns is likely to vary from one colour filter to another.

The filter 100 according to an embodiment of the invention therefore corresponds to a Fabry-Perot type transmission filter of the state of the art modified in that a discontinuous metal grating with a pattern repetition period strictly less than the transmission wavelength replaces one of the continuous reflectors of the filter. The other reflector remains a continuous thin metal film as in a known Fabry-Perot cavity filter.

Beneficially, the grating period is the same for all the spectral colour filters Fi, unlike the state of the art where the grating period is different for the different colour filters.

The transmission wavelength in the structure of each filter Fi can be obtained by optimising the thickness Ti of the dielectric cavity 103i according to the methods mentioned above and to a lesser extent the spacing Wi between each pattern of a metal grating 102i. The transmission passband corresponding to a given wavelength can be controlled by adjusting the spacing Wi between each pattern of a metal grating 102i and the thickness EG of the metal grating 102i.

The thickness EG of the metal gratings 102i is, in an embodiment, greater than the thickness EC of the continuous metal reflective layers 104i.

The thickness EG of the metal gratings 102i is, in an embodiment, greater than the penetration depth of the metal, that is, the (minimum) thickness of the metal at which the electromagnetic wave can be transmitted with minimal energy loss (the metal is more or less transparent), for the metal grating to act as a reflector. The thickness EG therefore has to be greater than this value (generally, the penetration depth of metals is about 5 to 10 nm).

As will be seen hereinafter, the filter 100 according to an embodiment of the invention makes it possible to obtain resonant filters at several wavelengths with a satisfactory maximum transmission for each wavelength and a sufficiently narrow and substantially constant passband for all wavelengths.

The filter 100 according to an embodiment of the invention also optionally includes a dielectric overlay 105 deposited above the continuous metal layers 104i.

The filter 100 according to an embodiment of the invention may also include a plurality of (at least two) photoelectric transducers not represented (here 4 photoelectric transducers would be necessary) facing each colour filter Fi. The transducers may be under the substrate 101, formed inside the latter or above the latter. The photoelectric transducers can operate either as collectors of light from the filters or as emitters of light towards the filters. In the case of collectors, the transducers can be, for example, CMOS-type photodiodes. In the case of emitters, the transducers can be, for example, LED diodes, QLED-type diodes or LASER diodes, in which case the emitters have a wider emission spectrum than that of the corresponding Fabry-Perot cavities.

In order to illustrate the performance of the filter according to an embodiment of the invention, FIG. 7 shows a comparison of the transmission spectra for three different colour filter structures:
Spectrum S1 with a colour filter having continuous thin metal layers of a Fabry-Perot filter according to the state of the art,
Spectrum S2 with a colour filter having a continuous layer and a metal grating as used in an embodiment of the present invention,
Spectrum S3 with a filter having a thick metal layer and a thinner metal layer as set forth in FIG. 2.

The comparison is made for a constant dielectric cavity thickness of 140 nm and the following filter structures:
(a) For the spectrum S1: Fabry-Perot filter with thin metal layers 30 nm thick,
(b) For the spectrum S2: Colour filter structure according to an embodiment of the invention where the lower metal layer is a metal grating. The grating period used for this illustration is 290 nm and the spacing between the metal patterns is 150 nm. The thickness of the metal grating is 60 nm,
(c) For the spectrum S3: Fabry-Perot filter with a continuous upper metal layer thickness of 30 nm and a continuous lower metal layer thickness of 60 nm.

In the simulation set forth, the angle of incidence is a normal angle, while a transverse magnetic polarisation is used.

Silver Ag is used here as the metal for the reflective layers and the cavity, the substrate and the covering material are made of SiO₂ with a constant refractive index of 1.46 for illustrative purposes. The choice of materials and dimensions is obviously not limited to those shown here.

As can be seen in FIG. 7, the use of a greater thickness of continuous metal layer (spectrum S3) makes it possible to narrow the transmission passband compared with that of the spectrum S1 of a standard Fabry-Perot filter: however, the increase in the thickness leads to a decrease in the maximum transmission. The use of a thick metal grating structure in accordance with an embodiment of the invention makes it possible to increase the transmission coefficient while still having a narrow passband (˜25 nm).

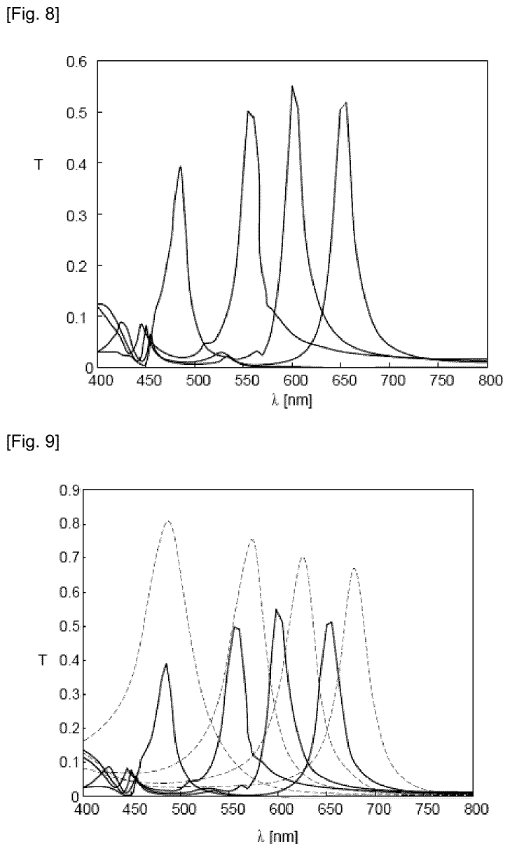

FIG. 8 shows the spectral response of a multispectral filter such as that in FIG. 6 with the following dimensions for each colour filter Fi:

| | F1 | F2 | F3 | F4 |
|---|---|---|---|---|
| P (nm) | 290 | 290 | 290 | 290 |
| Ti (nm) | 110 | 140 | 160 | 180 |
| Wi (nm) | 50 | 150 | 120 | 90 |
| λ (nm) | 485 | 555 | 600 | 655 |
| FWHM (nm) | ~25 | ~25 | ~25 | ~25 |

The thickness of the continuous reflective layer is equal to 30 nm for each colour filter and the thickness of the patterns of the metal grating for each colour filter is 60 nm.

It is noticed from FIG. 8 and the above table that it is possible by virtue of the filter according to an embodiment of the invention to obtain a quasi-constant narrow passband (the full width at half maximum FWHM is approximately equal to 25 nm whatever the colour) for all the wavelengths each corresponding to a given colour while keeping an identical repetition period P of the patterns of the metal gratings and by adjusting only the value of the spacing Wi between the patterns for each wavelength (the value of the wavelength being essentially set by the thickness Ti of the dielectric patterns of the Fabry-Perot cavity).

FIG. 9 shows the spectral response of FIG. 8, superimposed (in dotted lines) with the spectral response of a multispectral filter according to the state of the art with Fabry-Perot cavities and continuous reflective layers 30 nm thick.

The table below gives the full widths at half maximum for each of the colour filters for the filter according to an embodiment of the invention and the filter according to the state of the art respectively.

| | F1 | F2 | F3 | F4 |
|---|---|---|---|---|
| λ (nm) | 485 | 555 | 600 | 655 |
| FWHM (nm) filter | ~25 | ~25 | ~25 | ~25 |
| according to the | | | | |
| invention | | | | |
| FWHM (nm) filter | ~60 | ~40 | ~35 | ~30 |
| according to the | | | | |
| state of the art | | | | |

It is therefore noticed that, despite a higher maximum transmission, the filter according to the state of the art does not make it possible to obtain a substantially identical passband for each colour filter.

Furthermore, from the point of view of the manufacturing method, it is clear that the filter according to an embodiment of the invention offers more parameters to be varied in order to tune the wavelength, the maximum transmission and the passband, whereas the filter of the state of the art requires the wavelength to be set precisely as a function of the thickness of the dielectric pattern, without it being possible to correct or compensate for some of the limitations associated with manufacturing. Conversely, with the filter according to an embodiment of the invention, being able to vary the spacing Wi makes it possible to influence transmission and passband. Similarly, adjusting the period makes it possible to influence transmission and passband. Of course, it is also possible to alter the thickness of the patterns of the metal grating and/or the thickness of the metal layer to obtain the desired properties of the filter.

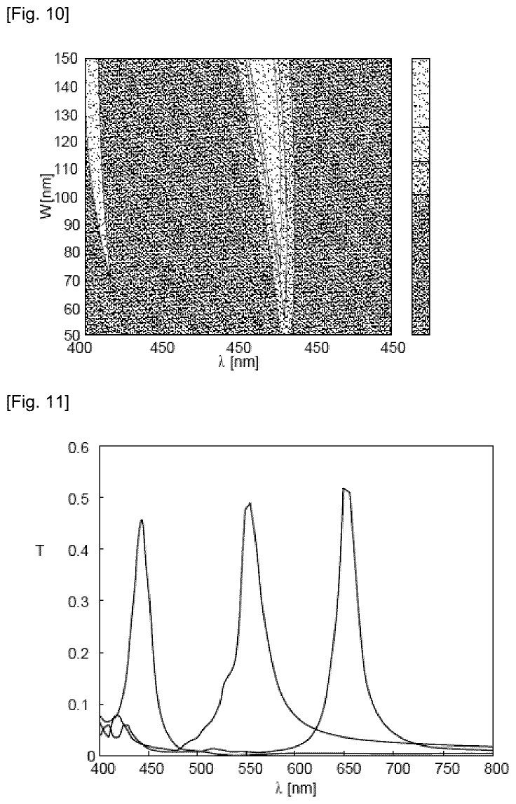

FIG. 10 shows a transmission mapping as a function of the spacing W between the patterns of a metal grating of a colour filter of a multispectral filter according to an embodiment of the invention, for a grating period of 290 nm and a dielectric cavity thickness of 180 nm. It can be seen that fine tuning of the wavelength can also be achieved by appropriate selection of the spacing W.

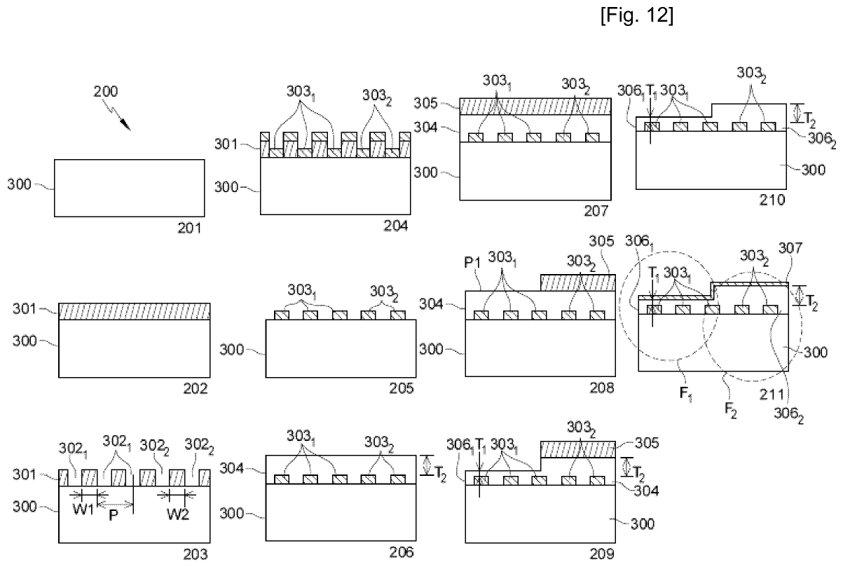

The selection of the repetition period P of the patterns of the metal grating can be arbitrary as long as this period is of smaller dimension than the wavelength (in other words, the period P has to be strictly smaller than the smallest wavelength to be filtered). The spacing Wi between the patterns can be optimised separately once the thickness Ti of the cavity has been determined. FIG. 11 shows another example of the spectral response of a multispectral filter according to an embodiment of the invention with a period P of 260 nm and predetermined cavity thicknesses Ti for filtering 3 colour channels (here specifically blue, green and red). The spacing Wi between the patterns of each metal grating corresponding to a colour has been optimised separately to obtain the highest possible transmission while having a narrow passband (always in the order of 25 nm) for each wavelength.

The dimensions of the multispectral filter according to an embodiment of the invention simulated in FIG. 11 are given in the table below for each colour filter Fi:

| | F1 | F2 | F3 |
|---|---|---|---|
| P (nm) | 260 | 260 | 260 |
| Ti (nm) | 90 | 140 | 180 |
| Wi (nm) | 70 | 130 | 70 |
| λ (nm) | 450 | 555 | 650 |
| FWHM (nm) | ~25 | ~25 | ~25 |

Incidentally, it will be noted that the spacings W1 and W3 are identical for different wavelengths of the respective colour filters F1 and F2.

FIG. 12 shows the different steps of a method 200 for manufacturing a multispectral filter according to an embodiment of the invention.

The first step 201 of the method 200 consists in starting with a substrate 300, which may for example be a Si substrate, a Silicon On Insulator (SOI) substrate or a glass or sapphire substrate.

Step 201 is followed by a step 202 consisting in depositing a resin layer 301 onto the substrate 300.

The method 200 then includes a step 203 of structuring the resin layer 301 to create spaces 302i by lithography by removing material from the resin layer 301: the spaces 302i are intended to receive the metal patterns of the metal grating of each colour filter. According to an embodiment of the invention, there should be at least two series of spaces corresponding to at least two colour filters. Here, for the sake of illustration only, two series of spaces 3021 and 3022 are represented, each corresponding to a colour filter. This step thus makes it possible to set not only the repetition period P in each metal grating (corresponding to the width of the resin pattern in each series to which the width of a space in the series is added) but also the spacing Wi (corresponding to the width of a pattern) between each pattern in a metal grating.

The method 200 then includes a step 204 of depositing metal both into the spaces 302i and also above the resin zones of the remaining layer 301. This deposition enables the metal patterns 303i to be formed in the spaces 302i for each of the metal gratings corresponding to a colour filter. The metal can be deposited conformally by Chemical Vapour Deposition (CVD) or Physical Vapour Deposition (PVD). The thickness of metal deposited is in the order of 60 nm, for example.

The metal deposition step is followed by a step 205 of removing the metal remaining on the resin and the remaining resin in order to keep only the metal patterns 303i.

The method 200 according to an embodiment of the invention then includes a step 206 of depositing a layer 304 of dielectric material intended to form the dielectric patterns of each of the colour filters of the filter according to the invention. This layer 304 is possibly planarised by an etching step possibly of the etch-back type and/or a CMP (Chemical Mechanical Polishing) polishing step. The material of the layer 304 is desirably, but not exclusively, a material that is transparent in the visible range, such as an organic material of the polymer or inorganic type (oxide, silicon nitride, alumina, etc.). The deposition is, for example, a deposition carried out by a physical vapour deposition (PVD) technique or a chemical vapour deposition (CVD) technique or a low pressure chemical vapour deposition (LPCVD) technique or a plasma enhanced chemical vapour deposition (PECVD) technique. It will be noted that the invention is not limited to the visible range and that other materials transparent to other wavelengths, in the infrared for example (for example, using silicon), can be used. It will be noted that the dielectric material fills the spaces between the metal patterns 303i. The thickness of the dielectric layer 304 (if necessary after planarisation) is chosen to correspond to the height of the thickest dielectric cavity (here referred to as the thickness T2) for all the colour filters.

Step 206 is followed by a step 207 of depositing a second resin layer 305 onto the dielectric layer 304.

According to step 208, the resin layer 305 is structured, for example by lithography, so as to reveal the zone P in the dielectric layer 304 corresponding to the dielectric pattern of the first colour filter to be formed.

Step 208 is followed by a step 209 during which the dielectric layer is etched in the zone P by a given thickness T1 so as to obtain the required thickness of the dielectric pattern 3061 of Fabry-Perot cavity. This etching may be dry or wet.

Steps 207 to 209 can be repeated on the hypothesis that more than two colour filters have to be obtained.

Step 210 then consists in removing the remaining resin 305 so as to release the dielectric pattern 3062 of Fabry-Perot cavity of thickness T2 on the surface.

Step 211 then consists in depositing a reflective metal layer 307, for example with a thickness of between 20 and 50 nm, covering the dielectric patterns 3061 and 3062 so as to form the continuous reflective layer of the colour filters F1 and F2 of the filter according to an embodiment of the invention. The two colour filters F1 and F2 are thus formed respectively by:
The gratings of metal patterns 3031 and 3032 of period P and spacing W1 and W2 respectively;
The dielectric cavity patterns 3061 and 3062;
The continuous metal reflective layer 307.

This planar continuous reflective layer 307 is deposited conformally by the CVD (Chemical Vapour Deposition) or PVD (Physical Vapour Deposition) method.

At the end of the manufacturing method according to this first embodiment of the invention, a multispectral filter is obtained in accordance with that shown in FIG. 6, wherein the metal gratings are located on the lower part of the filter and the continuous reflective layers are located on the upper part of the filter.

It will be seen hereinafter that it is also possible to have a multispectral filter according to a second embodiment of the invention.

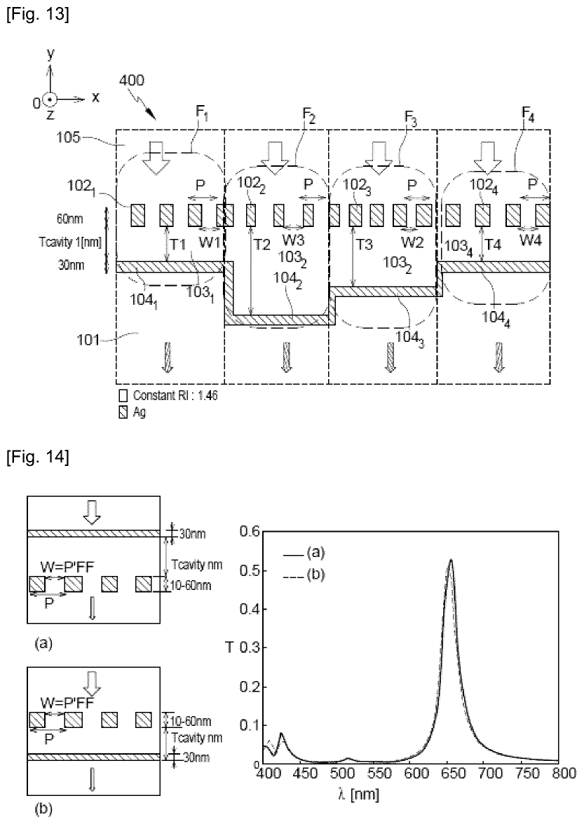

This filter 400 according to a second embodiment of the invention is represented schematically in FIG. 13. Its structure is identical to that of the filter according to the first embodiment of the invention represented in FIG. 6. The only difference between the filter 400 and the filter 100 consists in reversing the position of the continuous reflective metal layers 104i and the metal gratings 102i; thus, in FIG. 13, the metal gratings 102i are located on the upper part of the Fabry-Perot cavities whereas they were in the lower part in the filter in FIG. 6. For the sake of clarity, the reference numbers of the structural elements and dimensions are common to both filters 100 and 400

FIG. 14 shows the superposition of the spectral response of two colour filters, one used in the filter 100 of FIG. 6 (solid line) and the other used in the filter 400 of FIG. 13 (dotted line). The dimensions chosen are the same for both colour filters, with a dielectric pattern thickness T of 180 nm, a repetition period P of the metal patterns of the grating of 260 nm and a spacing W between the metal patterns of the grating of 70 nm. It is noticed that the two spectral responses are superimposed: it is therefore possible to use indiscriminately the structure of the filter 100 and the filter 400 without modifying the spectral response.

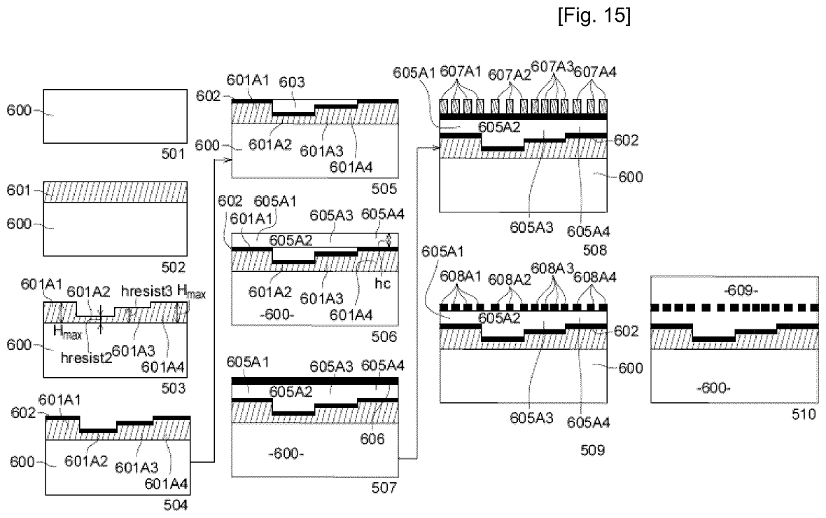

FIG. 15 shows the different steps of a method 500 for manufacturing a multispectral filter according to the second embodiment of the invention.

The first step 501 of the method 500 consists in starting with a substrate 600, which may for example be a Si substrate, a Silicon On Insulator (SOI) substrate or a glass or sapphire substrate.

Step 501 is followed by a step 502 consisting in depositing a resin layer 301 onto the substrate 300.

According to step 503, the resin layer 601 is then structured. Structuring the resin layer 601 is carried out by a lithography step. This lithography may be so-called grayscale lithography according to electronic or optical terminology. Other lithography techniques such as two-photon lithography or nanoimprint lithography can also be used for making the resin structure 601.

The resin layer 601 structured includes a plurality of patterns 601Ai (here 4 patterns 601A1, 601A2, 601A3 and 601A4).

According to the invention, there should be at least two resin patterns 601Ai of different heights. Among all these patterns 601Ai, one or more of them, in this case the patterns 601A1 and 601A4, have a maximum so-called reference height Hmax, the height being measured perpendicularly to the plane of the substrate 600. More generally, the height of the pattern 601Ai will be denoted as hᵣₑₛᵢₛₜ₋ᵢ. Thus, in FIG. 15, Hmax is equal to hᵣₑₛᵢₛₜ₋₁ and hᵣₑₛᵢₛₜ₋₄.

Step 503 is followed by a step 504 of depositing a reflective metal layer 602, for example with a thickness of between 20 and 50 nm, covering the patterns 601Ai of the underlayer 401 structured. This reflective layer 602 forms the first reflective layer of the Fabry-Perot cavity type colour filters to come. The reflective layer 602 should at least continuously cover each upper surface of the patterns 601Ai, it being understood that it could also be deposited onto the flanks of the patterns 601Ai. This reflective layer 602 is, for example, deposited conformally by the CVD (Chemical Vapour Deposition) or PVD (Physical Vapour Deposition) method. The conformal deposition makes it possible to have a constant thickness of the reflective layer 602, at least on the top of the patterns.

The next step, not represented, consists in depositing a layer made of the dielectric material intended to form the dielectric patterns of the Fabry-Perot cavities. The layer of dielectric material covers all the patterns 601Ai covered by the reflective layer 602. The layer has an upper surface (not necessarily planar), each point of which is located at a height, relative to the substrate 600, greater than the maximum reference height Hmax. The material of the layer is desirably, but not exclusively, a material that is transparent in the visible range, such as an organic material of the polymer or inorganic type (oxide, silicon nitride, alumina, etc.). The deposition is desirably a conformal deposition, for example carried out by a physical vapour deposition (PVD) technique or a chemical vapour deposition (CVD) technique or a low pressure chemical vapour deposition (LPCVD) technique or a plasma enhanced chemical vapour deposition (PECVD) technique.

The method 500 then includes a step 505 of planarising the layer made of the dielectric material intended to form the dielectric patterns of the Fabry-Perot cavities so as to form a layer 603 planarised at the surface by removal of the dielectric material from the dielectric layer previously deposited. Planarisation is performed with a stop on the reflective layer 602 located at its highest level (that is, at the reference height of the patterns 601A1 and 601A4).

The method 500 according to the invention then includes a step 506 of conformally depositing a layer 604 of the same dielectric material intended to form the dielectric patterns of the Fabry-Perot cavities. This step is carried out, for example, by a PVD, CVD, LPCVD or PECVD deposition technique. The height of the layer 604 is denoted as hc, the height being measured perpendicularly to the plane of the substrate 600. After this step, a plurality of dielectric patterns 605Ai of Fabry-Perot cavity are obtained (here four patterns 605A1, 605A2, 605A3 and 605A4).

The height hdiel_i of the pattern 605Ai can be determined according to the methods mentioned above. According to the method according to the invention, the height hdiel_i is determined by the following formula:

hdiel_i=Hmax−hᵣₑₛᵢₛₜ₋ᵢ+hc.

Thus, for the patterns 605A1 and 605A4, hdiel_1 and hdiel_4 are here directly equal to the height hc of layer 604.

More generally, for each pattern 605Ai, the height is determined technologically by the difference in height between that of the highest resin pattern 601A1 Hmax and the height of the resin pattern 601Ai, to which the height of the second dielectric layer 604 is added.

Step 507 of the method 500 then consists in depositing a second metal layer 606, with a thickness, in an embodiment, greater than that of the first metal layer 602, for example in the order of 60 nm, covering the patterns 605Ai of Fabry-Perot cavity. This planar and continuous metal layer 602 is intended to form the upper grating of metal patterns of Fabry-Perot cavity type colour filters. The metal layer 606 is deposited conformally by CVD or PVD deposition.

The method 500 then includes a step 508 of structuring a resin layer to create spaces 607Ai by lithography by removal of material in the resin layer.

The spaces 607Ai are intended to receive the metal patterns of the metal grating of each colour filter. According to an embodiment of the invention, there should be at least two series of spaces corresponding to at least two colour filters. Here, for the sake of illustration only, four series of spaces 607A1 to 607A4 are represented, each corresponding to a colour filter. This step thus makes it possible to set not only the repetition period P in each metal grating (corresponding to the width of the resin pattern in each series to which the width of one space in the series is added) but also the spacing Wi (corresponding to the width of one space in the series) between each pattern in a metal grating.

Step 509 then consists in etching the metal of the metal layer 606 not protected by the resin to create the metal patterns 308i in each of the metal gratings corresponding to a colour filter.

Step 510 consists in optionally depositing a planarised dielectric overlay 609 above and between the continuous metal pattern gratings.

The articles “a” and “an” may be employed in connection with various elements and components of compositions, processes or structures described herein. This is merely for convenience and to give a general sense of the compositions, processes or structures. Such a description includes “one or at least one” of the elements or components. Moreover, as used herein, the singular articles also include a description of a plurality of elements or components, unless it is apparent from a specific context that the plural is excluded.

It will be appreciated that the various embodiments and aspects of the inventions described previously are combinable according to any technically permissible combinations. For example, various aspects of the present disclosure may be used alone, in combination, or in a variety of arrangements not specifically described in the embodiments described in the foregoing and is therefore not limited in its application to the details and arrangement of components set forth in the foregoing description or illustrated in the drawings. For example, aspects described in one embodiment may be combined in any manner with aspects described in other embodiments.

The present invention has been described and illustrated in the present detailed description and in the figures of the appended drawings, in possible embodiments. The present invention is not however limited to the embodiments described. Other alternatives and embodiments may be deduced and implemented by those skilled in the art on reading the present description and the appended drawings.

In the claims, the term “includes” or “comprises” does not exclude other elements or other steps. The different characteristics described and/or claimed may be beneficially combined. Their presence in the description or in the different dependent claims do not exclude this possibility. The reference signs cannot be understood as limiting the scope of the invention.

1. A multispectral filter for electromagnetic radiation, said filter including at least two-colour filters, each colour filter including:
a metal grating including metal patterns repeated according to a given period, each metal pattern being spaced apart from an adjacent metal pattern by a given non-zero spacing;
a continuous reflective layer;
a pattern of dielectric material of Fabry-Perot cavity between the metal grating and the continuous reflective layer;
a thickness of the patterns of dielectric material of the two-colour filters being different.

2. The multispectral filter according to claim 1, wherein a repetition period of the metal patterns is identical for the two-colour filters.

3. The multispectral filter according to claim 1, wherein a thickness of the metal grating of the two-colour filters is identical.

4. The multispectral filter according to claim 1, wherein a thickness of the reflective layer of the two-colour filters is identical.

5. The multispectral filter according to claim 1, wherein each of the two filters faces a photoelectric transducer.

6. The multispectral filter according to claim 1, wherein the space between each metal pattern is filled with the dielectric material forming the patterns of dielectric material of Fabry-Perot cavity of the colour filters.

7. The multispectral filter according to claim 1, wherein a repetition period of the metal patterns of each metal grating is chosen to be strictly less than a wavelength of the corresponding colour filter.

8. A method for manufacturing a multispectral filter for electromagnetic radiation according to claim 1, comprising:
depositing a first resin layer onto a substrate;
structuring the first resin layer so as to obtain at least two series of trenches in the first resin layer, each trench in a series being spaced apart from an adjacent trench in the series by a given non-zero spacing, the trenches being repeated according to a given period;
depositing a metal layer into the trenches and onto the remaining resin;
removing the remaining resin and the metal being on the remaining resin so as to keep two metal gratings each including metal patterns repeated according to the given period of one of the series of trenches, each metal pattern being spaced apart from an adjacent metal pattern by the given non-zero spacing of one of the series of trenches;
depositing a planar layer of dielectric material intended to form at least two patterns of dielectric material of Fabry-Perot cavity, said layer having the maximum thickness of the dielectric pattern of Fabry-Perot cavity;
depositing a resin layer onto the layer of dielectric material and removing said resin layer with a stop on the dielectric layer at the zone above one of the two metal gratings;
etching the dielectric layer at the resin removal zone so as to obtain a first dielectric pattern of Fabry-Perot cavity;
removing the remaining resin so as to reveal a second dielectric pattern of Fabry-Perot cavity having the maximum dielectric pattern thickness, the thickness of the first dielectric pattern being less than the thickness of the first dielectric pattern, and
depositing a continuous metal layer onto the first and second dielectric patterns.

9. A method for manufacturing a multispectral filter for electromagnetic radiation according to claim 1, comprising:
depositing a layer of structuring material onto a substrate;
structuring the layer of structuring material so as to obtain at least two structuring material patterns of different heights, at least one of the patterns having a maximum reference height relative to the substrate, the height being measured perpendicularly to the plane of the substrate;
depositing a continuous metal layer onto the at least two structuring material patterns;
depositing a layer made of the dielectric material intended to form at least two dielectric patterns of Fabry-Perot cavities, said layer of dielectric material covering all the structuring material patterns and having an upper surface, each point of which is located at a height greater than the maximum reference height;
planarising by removal of the dielectric material with a selective stop at the top of the uppermost structuring material pattern covered by the continuous metal layer;
depositing a layer made of the same dielectric material so as to finalise the formation of the at least two dielectric patterns of Fabry-Perot cavity;
depositing a second metal layer onto the at least two dielectric patterns of Fabry-Perot cavity, and
structuring the second metal layer so as to form at least two metal gratings each including metal patterns repeated according to a given period, each metal pattern being spaced apart from an adjacent metal pattern by a given non-zero spacing.

10. The manufacturing method according to claim 11, wherein the structuring material is a resin, said structuring step being carried out by a Grayscale lithography step on the layer of structuring material.
